(19) United States
(12) Patent Application Publication
(10) Pub. No.: US 2010/0065194 A1
(43) Pub. Date: Mar. 18, 2010

(54) Method for manufacturing printed wiring board

(75) Inventors: Kenji Nagase, Tokyo (JP); Hiroyuki Uematsu, Tokyo (JP); Kenichi Kawabata, Tokyo (JP)

Correspondence Address: OLIFF & BERRIDGE, PLC, P.O. BOX 320850, ALEXANDRIA, VA, 22320-4850, US

(73) Assignee: TDK CORPORATION, Tokyo (JP)

(21) Appl. No.: 12/461,245

(22) Filed: Aug. 5, 2009

(30) Foreign Application Priority Data
Sep. 17, 2008 (JP) 2008-238268

(51) Int. Cl. H05K 3/06

(52) U.S. Cl. 156/230

(57) ABSTRACT

To provide a method for manufacturing a printed wiring board which can easily and surely form a fine wiring pattern having a small layer thickness while enhancing the productivity by simplifying a process, when forming a wiring structure having a filled via. The method for manufacturing a printed wiring board according to the present invention includes: bonding a metal foil 20 provided with a carrier foil having a carrier foil layer 22 and a metal foil layer 21 onto a resin substrate 11 (insulator) so that the metal foil layer 21 can contact one surface of the resin substrate 11; subsequently forming a via hole V (connection hole); filling the via with a film 32 formed by plating; then peeling the carrier foil layer 22 of the metal foil 20 provided with the carrier foil from the metal foil layer 21; and patterning the metal foil layer 21 which remains on the resin substrate 11 in a bonded state to form a wiring pattern 23.

### BACKGROUND OF THE INVENTION

1. Field of the Invention

The present invention relates to a method for manufacturing a printed wiring board.

2. Description of the Related Art

As for a conventional high-density packaging structure of a printed wiring board, a module or a packaging structure is known which uses a printed wiring board in a multilayer structure having a conductive layer and an insulating layer alternately stacked thereon, and has an active component such as a semiconductor IC chip (bear chip or die) or a passive component such as a resistor and a capacitor embedded therein. Such a multilayer structure generally has connection holes such as a via hole and a contact hole formed in between interlayers, and these connection holes are used to electrically connect a conductive layer with an electrode of the embedded electronic component provided in different layers by using a conductor (so-called filled via) embedded in those connection holes. When such a filled via is used, a via can be further provided thereon (via on via), which makes it needless to form an extra wiring pattern for a pad for external connection, and accordingly is useful to realize multilayer high-density wiring.

In order to form such a filled via and a wiring pattern, there is a method of filling the via hole (via filling) with a conductor and forming the conductive layer for the wiring pattern simultaneously with a plating technique. In this case, on such a plating condition as to surely fill the inner part of the via hole with the conductor, a “thick” wiring pattern having a plated thickness which is dependent on a depth of the via hole (thickness of filled via) is unavoidably formed, so that a fine wiring pattern having a small layer thickness has tended to be hardly formed.

For this reason, as a method for forming a fine wiring pattern while forming the filled via, for instance, Japanese Patent Application Laid-Open No. 2008-47788 discloses a method of conducting plating individually for forming the field via and for forming the conductor pattern. In addition, Japanese Patent Application Laid-Open No. 2008-21770 discloses a method of conducting plating for forming the filled via several divided times. Furthermore, Japanese Patent Application Laid-Open No. 2006-339483 discloses a method of forming the filled via and another conductor film than the filled via simultaneously with a plating technique, and then etching the plated conductor except the filled via back to a desired thickness with an electrolytic etching technique.

However, any of the methods described in Patent documents 1 and 2 needs to carry out a plurality of plating processes and a step of forming a resist pattern accompanying the processes, consequently needs complicated steps and cannot sufficiently enhance the productivity.

In addition, the method described in the above described Japanese Patent Application Laid-Open No. 2006-339483 also needs a back etching step and a step of forming a resist pattern accompanying the step, and consequently results in needing complicated steps. In addition, in this case, the distribution of the thickness of the conductor occurring when the conductor is back etched results in being added to the distribution of the thickness of the conductor occurring when the conductor is formed by plating at first, so that it becomes difficult to sufficiently secure the uniformity of the thickness of the wiring pattern, and that there has been a limitation in thinning the layer of the wiring pattern.

For this reason, the present invention is designed with respect to such circumstances, and is directed at providing a method for manufacturing a printed wiring board which can easily and surely form a fine wiring pattern having a small layer thickness while enhancing the productivity by simplifying the process, when forming a wiring structure having a filled via.

### SUMMARY OF THE INVENTION

In order to solve the above described problems, a method for manufacturing a printed wiring board according to the present invention includes the steps of: forming a conductive layer on the other surface of an insulator; bonding a metal foil provided with a carrier foil having a carrier foil layer and a metal foil layer onto the insulator so that the metal foil layer can contact one surface of the insulator; forming at least one hole in the metal foil provided with the carrier foil and the insulator so that the conductive layer formed on the other surface of the insulator can be exposed from the metal foil provided with the carrier foil; filling the hole with a conductor by conducting plating on the metal foil provided with the carrier foil and on the inner part of the hole; and peeling the carrier foil layer of the metal foil provided with the carrier foil from the metal foil layer. However, any of the step of forming the conductive layer on the other surface of the insulator and the step of bonding the metal foil provided with the carrier foil to one surface of the insulator may be previously carried out, or the steps may be simultaneously carried out.

In a method for manufacturing a printed wiring board having such a structure, the metal foil provided with the carrier foil including the carrier foil layer and the metal foil layer is bonded to one surface of the insulator, and the conductive layer is formed on the other surface of the insulator. Then, at least one hole is formed in the metal foil provided with the carrier foil and the insulator, and the conductive layer provided in the rear face side of the metal foil provided with the carrier foil is exposed to the inner part of the hole. In this state, a conductor is plated on one face side of the insulator, in other words, on the metal foil provided with the carrier foil to fill the inner part of the hole (via filling) with the conductor, and the conductor (filled via) filled in the hole is consequently connected with a metal layer of the metal foil provided with the carrier foil. At this time, a plated conductor having a comparatively large thickness which is dependent on the thickness of the plated conductor filled in the hole is also formed on the metal foil provided with the carrier foil, but the plated conductor in that portion is removed by being peeled from the metal foil layer (in other words, insulator side) together with the carrier foil layer. Thereby, only the metal foil layer connected to the conductor in the hole remains in a bonded state on one side surface of the insulator.

The metal foil layer of the metal foil provided with the carrier foil can be previously formed into a layer form having extremely small thickness and superior uniformity, so that a filled via structure which is the hole filled with the conductor is formed by only peeling and removing the carrier foil layer from the metal foil layer, and that a thin conductor (metal foil layer) can be formed in the same layer as the filled via structure. Then, a fine wiring pattern can be obtained by patterning the conductor. Thus, more specifically, the method for manufacturing the printed wiring board may include a step of forming a wiring pattern in a metal foil layer bonded to one surface of the insulator.

In addition, a material for the carrier foil layer of the metal foil provided with the carrier foil is not limited in particular as long as a seed layer (substratum conductive layer) for electrolytic plating (electroplating) can be formed thereon in a plating step, and is preferably a metal (which may be single metal, alloy or complex metal) from the viewpoint of easily forming the seed layer thereon and being superior in heat resistance when heat-treated in a photolithographic process and an etching process- Furthermore, when the metal foil layer is deposited on an electrode of the carrier foil layer with an electrolytic method so as to form the metal foil provided with the carrier foil, the carrier foil layer needs to have electroconductivity, and in this regard as well, the carrier foil layer is preferably a metal or may be an electroconductive function film.

Here, the step of forming the hole may also include a step of forming at least one aperture in the metal foil provided with the carrier foil so that one surface of the insulator can be exposed from the metal foil with the carrier foil; and a step of forming at least one connection hole in the insulator under at least one aperture so that the conductive layer formed on the other surface of the insulating layer can be exposed. In this case, the “hole” is configured by the aperture and the connection hole.

By doing this, in the step of forming the hole, at least one part of the metal foil provided with the carrier foil is opened, one part of the insulator is exposed, subsequently a connection hole is formed in at least one portion at which the insulator is exposed, and the conductive layer provided in the rear face side of the metal foil provided with the carrier foil is exposed to the inner part of the connection hole. In this state, a conductor-is plated on one face side of the insulator, in other words, on the metal foil provided with the carrier foil, on one surface of the insulator (when connection hole has smaller diameter than that of aperture) and in the inner part of the connection hole, and the connection hole is filled with the conductor.

Furthermore, the present invention is extremely useful when the connection hole is formed by making a working (processing) medium (media) having a larger beam diameter or shot diameter than that of the aperture project to or irradiate the insulator from above the aperture, in the step of forming the hole in the insulator. Here, a method for forming the connection hole includes laser treatment, wet blast treatment, dry blast treatment, desmear treatment, plasma (ashing) treatment, jet scrub treatment and ultrasonic treatment, for instance.

When the connection hole is formed by using a working medium having a smaller beam diameter (when working medium is substantially continuous flow) or shot diameter (when working medium is substantially intermittent flow or pulse) than that of the aperture such as a mask (so-called large window processing), the working medium is not projected to or irradiates the mask usually, so that the mask is not damaged. On the other hand, when the connection hole is formed by using a working medium having a larger beam diameter or shot diameter than that of the aperture of the mask or the like (so-called conformal processing), one part of the mask may be damaged (etched) by the working medium which has been projected to or has irradiated the mask. Then, when the mask is formed of the conductive layer for forming a wiring pattern therein, the wiring pattern is difficult to be formed into a desired pattern in the following step, which may cause the inconvenience of disconnection or the like. In contrast to this, when the aperture is provided in the metal foil provided with the carrier foil and the metal foil having the aperture is used as a mask for processing, the carrier foil layer of the metal foil provided with the carrier foil shields the working medium, and the working medium is not directly projected to or does not directly irradiate the metal foil layer, so that the metal foil provided with the carrier foil can surely inhibit the metal foil layer in which the wiring pattern will be formed later from being damaged.

The method for manufacturing a printed wiring board according to the present invention bonds a metal foil provided with a carrier foil having a carrier foil layer and a metal foil layer onto an insulator so that the metal foil layer can contact one surface of the insulator, then forms a hole, fills the via with a metal, and then peels the carrier foil layer of the metal foil provided with the carrier foil from the metal foil layer; and accordingly can surely form a fine wiring pattern having a small layer thickness from the metal foil layer while enhancing the productivity by simplifying the process, when forming a wiring structure having a filled via.

### BRIEF DESCRIPTION OF THE DRAWINGS

FIGS. 1(A) to (D) are process flow charts illustrating an outline of a state of manufacturing a printed wiring board according to one embodiment of a method for manufacturing a printed wiring board according to the present invention;

FIGS. 2(A) to (C) are process flow charts illustrating an outline of a state of manufacturing a printed wiring board according to one embodiment of a method for manufacturing a printed wiring board according to the present invention;

FIGS. 3(A) to (D) are process flow charts illustrating an outline of a state of manufacturing a printed wiring board according to another embodiment of a method for manufacturing a printed wiring board according to the present invention;

FIGS. 4(A) to (C) are process flow charts illustrating an outline of a state of manufacturing a printed wiring board according to another embodiment of a method for manufacturing a printed wiring board according to the present invention;

FIGS. 5(A) to (D) are process flow charts illustrating an outline of procedural steps in one embodiment (with existence of foreign matter) of a method for manufacturing a printed wiring board according to the present invention;

FIGS. 6(A) to (C) are process flow charts illustrating an outline of procedural steps in one embodiment (with existence of foreign matter) of a method for manufacturing a printed wiring board according to the present invention; and

FIGS. 7(A) to (E) are process flow charts illustrating an outline of procedural steps in one example (with existence of foreign matter) of a conventional method for manufacturing a printed wiring board.

### DETAILED DESCRIPTION OF THE PREFERRED EMBODIMENTS

Embodiments according to the present invention will now be described below with reference to the drawings. In the drawings, the same reference numerals will be put on the same elements, and overlapping descriptions will be omitted. A positional relation such as up, down, left and right may be based on the positional relation as is illustrated in the drawings, unless otherwise specifically indicated. A dimensional ratio in the drawings is not limited to the shown ratio. The following embodiments are illustrated for describing the present invention, and the present invention is not limited to the embodiments. Furthermore, the present invention can be modified in various ways insofar as they do not deviate from the scope of the invention.

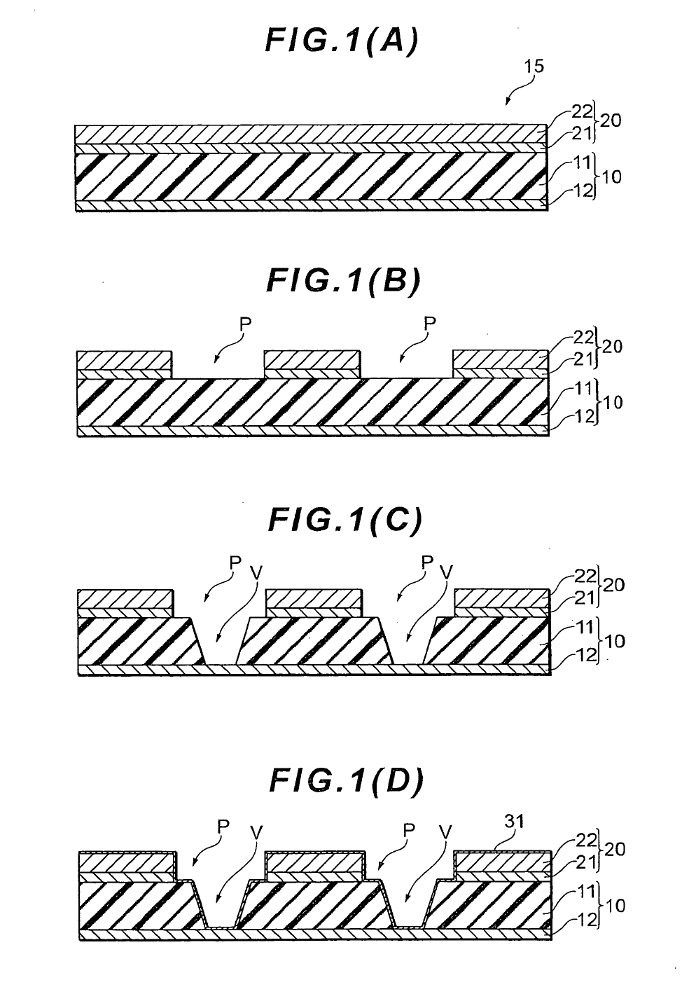

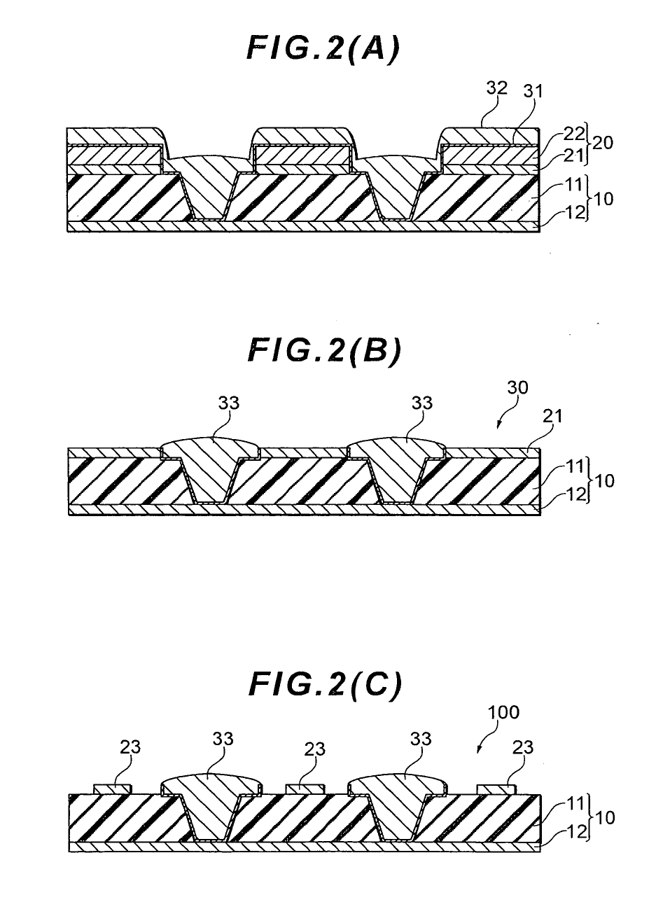

FIGS. 1(A) to (D) and FIGS. 2(A) to (C) are process flow charts illustrating an outline of a state of manufacturing a printed wiring board according to one preferred embodiment of a method for manufacturing a printed wiring board according to the present invention, and schematic sectional views illustrating one part of the printed wiring board in each step. The method for manufacturing the printed wiring board according to the present embodiment can be applied to various cases of manufacturing the printed wiring board, for instance, to the case of mounting electronic components of active components such as a semiconductor IC chip and active components such as a resistance and a capacitor on a core substrate constituting a base material of a substrate module which embeds them therein, to the case of mounting the electronic components on a so-called buildup layer to be formed on the core substrate, and the like.

In the present embodiment, firstly, a core substrate 10 is prepared (FIG. 1(A)). The type of the core substrate 10 is not limited in particular, but is, for instance, a resin substrate having a metal foil on one side, which has a so-called RCC (Resin Coated Copper) structure of having a metal foil layer 12 (conductive layer) such as a copper foil formed on one side (other face: other side) of a resin substrate 11 (insulator), and plays a role in securing a mechanical strength of the whole printed wiring board.

A resin material to be used for the resin substrate 11 can specifically include, for instance: a simple substance of a vinylbenzyl resin, a resin of a polyvinylbenzyl ether compound, a bismaleimidetriazine resin (BT resin), a polyphenylene ether (polyphenylene ether oxide) resin (PPE or PPO), a cyanate ester resin, an epoxy +active ester curable resin, a polyphenylene ether resin (polyphenylene oxide resin), a curable polyolefin resin, a benzocyclobutene resin, a polyimide resin, an aromatic polyester resin, an aromatic liquid crystal polyester resin, a polyphenylene sulfide resin, a polyetherimide resin, a polyacrylate resin, a polyether ether ketone resin, a fluorine resin, an epoxy resin, a phenol resin and a benzoxazine resin; a material containing any of those resins and additionally any of silica, talc, calcium carbonate, magnesium carbonate, aluminum hydroxide, magnesium hydroxide, aluminum borate whiskers, potassium titanate fiber, alumina, glass flake, glass fiber, tantalum nitride and aluminum nitride; further a material containing any of those resins and additionally containing a powder of a metal oxide which contains at least one metal among magnesium, silicon, titanium, zinc, calcium, strontium, zirconium, tin, neodymium, samarium, aluminum, bismuth, lead, lanthanum, lithium and tantalum; and still further a material of these resins blended with a resin fiber such as a glass fiber and an alamido fiber, or a material of a glass cloth, an alamido fiber or a non-woven fabric impregnated with these resins. A material to be used can be appropriately selected from the viewpoint of electric characteristics, mechanical characteristics, absorbency, reflow resistance or the like. In addition, the thickness of the material can be approximately 20 μm to 200 μm, for instance. Furthermore, a sheet material such as LCP, PPS, PES, PEEK and PI containing no core material may also be employed in order to uniformize the working (processing) condition.

On the other hand, the thickness of the metal foil layer 12 can be approximately 1 μm to 18 μm, for instance. An electrolytic copper foil (prepared by continuously electrodepositing copper on an electrodeposition roll to form the copper foil from an aqueous solution of copper sulfate, in which copper is dissolved and ionized), which is used for a printed wiring board, or a rolled copper foil is used as the metal foil layer 12. The rolled copper foil is preferably used because of being capable of making the variation of its thickness extremely diminished. The thickness of the metal foil layer 12 can also be adjusted by a technique of sweeping or the like, as needed.

Next, a composite 15 having a so-called double-sided CCL (Copper Clad Laminate) structure can be obtained by bonding a metal foil 20 provided with a carrier foil to the opposite face (one face: face in one side) to the metal foil layer 12 in the core substrate 10 (FIG. 1(A)). The metal foil 20 provided with the carrier foil is formed by laminating a metal foil layer 21 such as copper to be joined to the core substrate 10, with a carrier foil layer 22 through an organic joining layer (not shown) of a nitrogen-containing organic compound such as a substituted triazole compound, a sulfur-containing organic compound such as mercaptobenzothiazole, and a carboxylic acid.

The carrier foil layer 22 is not limited in particular as long as a seed layer for electroplating can be formed thereon in a plating step, and may be an insulator such as a resin, but is preferably a metal from the viewpoint of easily forming the seed layer thereon and showing superior heat resistance when being heat-treated later as the printed wiring board. In addition, when the metal foil layer 21 is deposited on the carrier foil layer 22 which is used for the electrode with an electrolytic method so as to form the metal foil 20 provided with the carrier foil, the carrier foil layer 22 needs to have electroconductivity, and in this regard, the carrier foil layer 22 can employ a metal or an electroconductive function film. Such a metal foil 20 provided with the carrier foil and the manufacturing method therefor include those described in U.S. Pat. No. 3,370,636, for instance.

Subsequently, at least one aperture P is formed on the core substrate 10 by selectively removing and patterning the metal foil 20 provided with the carrier foil of the composite 15 with the use of a photolithographic technology and an etching technique, and one part of the resin substrate 11 is exposed (FIG. 1(B)).

Subsequently, a via hole V (connection hole) is formed by making the working medium such as a laser beam and blast beads project to or irradiate the resin substrate 11 in a portion exposed to the aperture P, while using the metal foil 20 provided with the carrier foil having the aperture P formed therein, as a mask, and making the metal foil layer 12 formed on the other surface of the resin substrate 11 be exposed (FIG. 1(C)). A treatment method to be used at this time includes laser treatment, wet blast treatment, dry blast treatment, desmear treatment, plasma (ashing) treatment, jet scrub treatment and ultrasonic treatment, for instance. Thus, the “hole” according to the present invention is configured by the aperture P and the via hole V.

At this time, if the connection hole was formed by using a working medium having a smaller beam diameter or shot diameter than that of the aperture P (so-called large window process), a via hole V having a smaller diameter than that of the aperture P would be formed, as is illustrated in FIG. 1(C). Alternatively, when the connection hole is formed by using a working medium having a larger beam diameter or shot diameter than that of the aperture P (so-called conformal process), the aperture diameter (upper aperture diameter) of the via hole V shall be the same diameter as that of the aperture P.

Next, a seed layer 31 is formed almost all over the upper exposed surface in this state (upper surface of metal foil 20 provided with carrier foil, exposed surface of resin substrate 11, and inner wall surface of via hole V) (FIG. 1(D)). A method to be employed for forming the seed layer 31 is preferably an electroless plating method, but can also be a sputtering method, a vapor deposition method or the like. The seed layer 31 plays a role of a substratum conductive layer for the electrolytic plating which will be carried out later, and accordingly may be extremely thin. For instance, the thickness may be appropriately selected from a range of several tens of nanometers to several micrometers. Subsequently, the seed layer 31 is grown by an electrolytic plating method. The plated film 32 is formed almost all over the exposed surface including the inner wall surface of the via hole V, and fills the inner part of the via hole V (via filling; FIG. 2(A)).

Then, the carrier foil layer 22 of the metal foil 20 provided with the carrier foil is peeled from the metal foil layer 21. The metal foil layer 21 adheres to one surface of the core substrate 10, and a structure 30 is obtained which has a filled via 33 therein which is the via hole V filled with the plated film (FIG. 2(B)). Furthermore, a wiring pattern 23 is formed in the surface layer (outer layer) of the structure 30 by selectively removing and patterning the metal foil layer 21, with the use of a photolithographic technology and an etching technique. Thus, a printed wiring board 100 is obtained (FIG. 2(C)). The multilayer structure can be obtained by sequentially stacking a via on a via, an insulator and a conductive layer by using the wiring pattern 23 as a conductor pattern of the first layer.

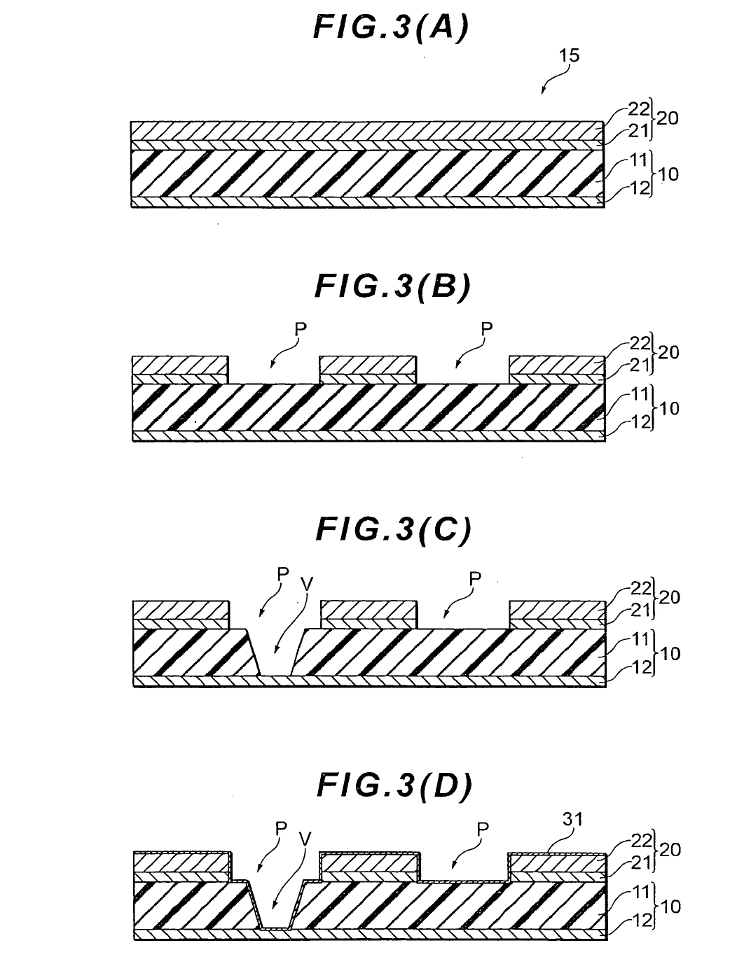

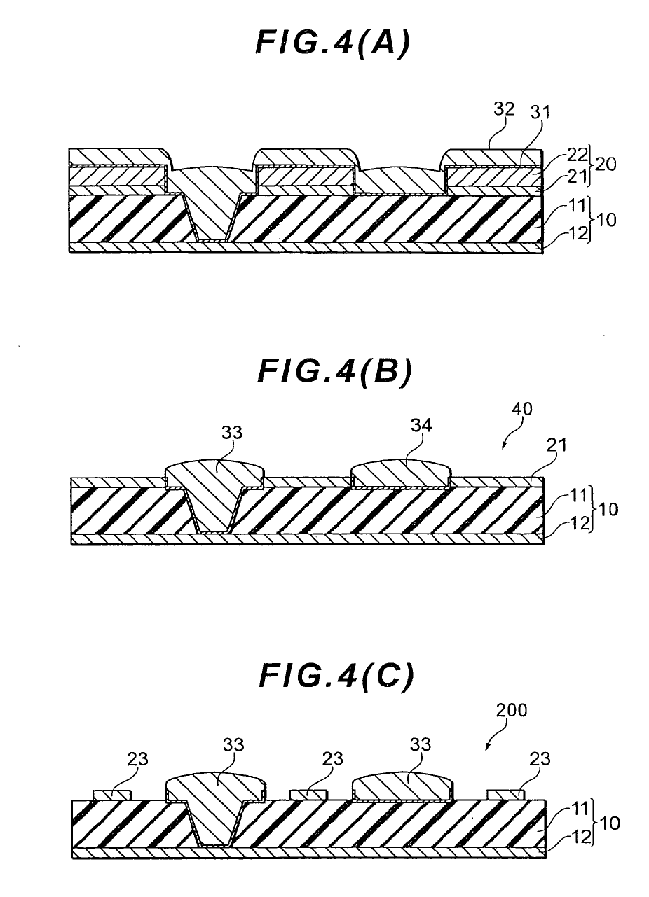

FIGS. 3(A) to (D) and FIGS. 4(A) to (C) are process flow charts (flow charts) illustrating an outline of a state of manufacturing a printed wiring board according to another preferred embodiment of a method for manufacturing a printed wiring board according to the present invention, and schematic sectional views illustrating one part of the printed wiring board in each step.

In the present embodiment, according to the same procedural steps (procedures) as were described in FIGS. 1(A) and (B), at least one aperture P is formed on the core substrate 10 by selectively removing and patterning the metal foil 20 provided with the carrier foil of the composite 15 having a double-sided CCL structure in which the metal foil 20 provided with the carrier foil is bonded to the opposite face to the metal foil layer 12 in the core substrate 10, with the use of a photolithographic technology and an etching technique, and one part of the resin substrate 11 is exposed (FIGS. 3(A) and (B)). Subsequently, a via hole V is formed on the resin substrate 11 in one part of the aperture P, and the metal foil layer 12 in that portion is exposed (FIG. 3(C)).

Next, a seed layer 31 is formed almost all over the upper exposed surface in this state (upper surface of metal foil 20 provided with carrier foil, exposed surface of resin substrate 11, and inner wall surface of via hole V), in a similar way to that in the above description (FIG. 3(D)). Next, the seed layer 31 is grown by an electrolytic plating method. The plated film 32 is formed almost all over the exposed surface including the inner wall surface of the via hole V, and fills the inner part of the via hole V (via filling; FIG. 4(A)). At this time, the inner part of an aperture P having the via hole V not formed-therein is also filled with the plated film 32.

Then, a carrier foil layer 22 of the metal foil 20 provided with the carrier foil is peeled from a metal foil layer 21. The metal foil layer 21 adheres to one surface of the core substrate 10, and a structure 40 is obtained which has a filled via 33 therein which is a via hole V filled with the plated film and has a conductor 34 therein which fills the aperture P having the via hole V not formed therein (FIG. 4(B)). Furthermore, a wiring pattern 23 is formed in the surface layer (outer layer) of the structure 40 by selectively removing and patterning the metal foil layer 21 with the use of a photolithographic technology and an etching technique. Thus, a printed wiring board 200 is obtained (FIG. 4(C)).

According to printed wiring boards 100 and 200 manufactured in this way and the manufacturing method therefor, a plated film 32 having a comparatively large thickness which is dependent on the thickness of the plated film 32 filled in the via hole V is also formed on a metal foil 20 provided with a carrier foil, but the plated film 32 on the metal foil 20 provided with the carrier foil is removed by being peeled from the metal foil layer 21 together with the carrier foil layer 22, as is illustrated in FIG. 2(A) and FIG. 4(A). Thereby, only the metal foil layer 21 which forms the same layer as a filled via 33 in the via hole V and is connected to the filled via 33 remains on a resin substrate 11 of a core substrate 10 in a state of being bonded to the resin substrate 11. The metal foil layer 21 of the metal foil 20 provided with the carrier foil can be previously formed into a layer form having extremely small thickness and superior uniformity, so that the filled via 33 which is the via hole V filled with the plated conductor is formed by only peeling and removing the carrier foil layer 22 from the metal foil layer 21, and that a thin conductor (metal foil layer 21) can be formed in the same layer as the filled via 33. Then, a fine wiring pattern 23 can be easily obtained by patterning the metal foil layer 21.

In addition, a conductor 34 and a wiring pattern 23 which have different thicknesses can be formed as the same layer simultaneously by forming an aperture P in the metal foil 20 provided with the carrier foil in a portion at which the via hole V is not formed and by forming a plated film therein, without increasing the number of steps as is illustrated in FIGS. 3(A) to (D) and FIGS. 4(A) to (C). In this case, the printed wiring board 200 has the advantage of being capable of reducing a conductor loss by using the conductor 34 having a comparatively large thickness for wiring in which a large electric current flows, and being capable of further promoting the miniaturization of the wiring pattern 23 by using the wiring pattern 23 having a comparatively small thickness as a signal line.

When a metal is used for the carrier foil layer 22 of the metal foil 20 provided with the carrier foil, a seed layer 31 is more easily formed thereon than the case in which a resin is used, and the metal can enhance heat resistance in heat treatment in a photolithographic process and an etching process.

Furthermore, when the via hole V is formed by a conformal processing, a working medium such as a laser beam is shielded by the carrier foil layer 22 of the metal foil 20 provided with the carrier foil, and is not directly projected to or does not irradiate the metal foil layer 21, so that the carrier foil layer 22 can surely inhibit the metal foil layer 21 in which the wiring pattern 23 will be formed later from being damaged.

Furthermore, when a foreign matter such as a fine particle and dust deposits on a substrate before the substrate is subjected to plating treatment, the used metal foil 20 provided with the carrier foil can prevent the inconvenience due to the deposition of such a foreign matter.

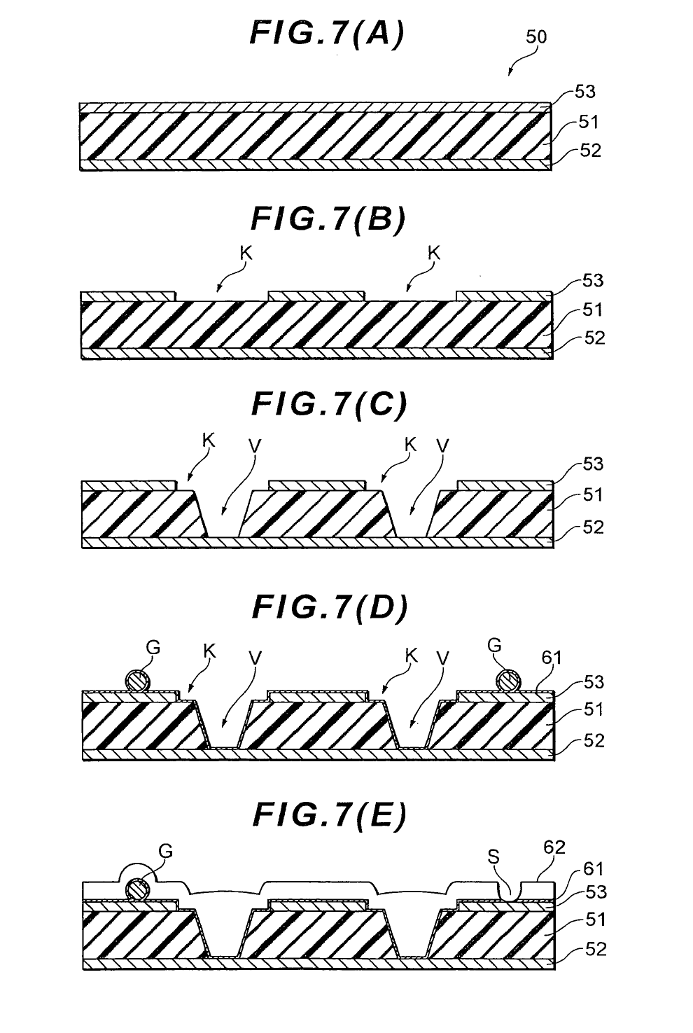

Here, FIGS. 7(A) to (E) are process flow charts illustrating an outline of procedural steps in one example of a conventional method for manufacturing a printed wiring board. A core substrate 50 is a composite having a double-sided CCL structure in which copper foil layers 52 and 53 are provided on both sides of a resin substrate 51. Here, a plurality of apertures K are formed on the core substrate 50 by selectively removing and patterning the copper foil layer 53 of the prepared core substrate (FIG. 7(A)) with the use of a photolithographic technology and an etching technique, and one part of the resin substrate 51 is exposed (FIG. 7(B)).

Subsequently, a via hole V is formed by irradiating the resin substrate 51 in a portion exposed in the aperture K with a laser beam while using the copper foil layer 53 having the aperture K formed therein as a mask, in a large window process, and the copper foil layer 52 in the other surface side of the resin substrate 51 is consequently exposed (FIG. 7(C)). Furthermore, a seed layer 61 is formed almost all over the upper exposed surface of this state (upper surface of copper foil layer 53, exposed surface of resin substrate 51 and inner wall surface of via hole V), by an electroless plating method. At this time, when a foreign matter G such as a fine particle and dust deposited on the copper foil layer 53 or deposits on the copper foil layer 53 on the way, the seed layer 61 can be formed so as to take in the foreign matter G (FIG. 7(D)). When the seed layer 61 is grown by conducting an electrolytic plating process in this state, a plated film 62 to be a wiring layer which will form the same layer as a filled via is formed almost all over the exposed surface including the inner wall surface in the via hole V. However, when the foreign matter G falls, the film forms the ununiformity of the film thickness therein due to the unevenness which is a recess part (dropout portion S) produced in the plated film 62, or a projecting part formed in a portion at which the foreign matter G remains.

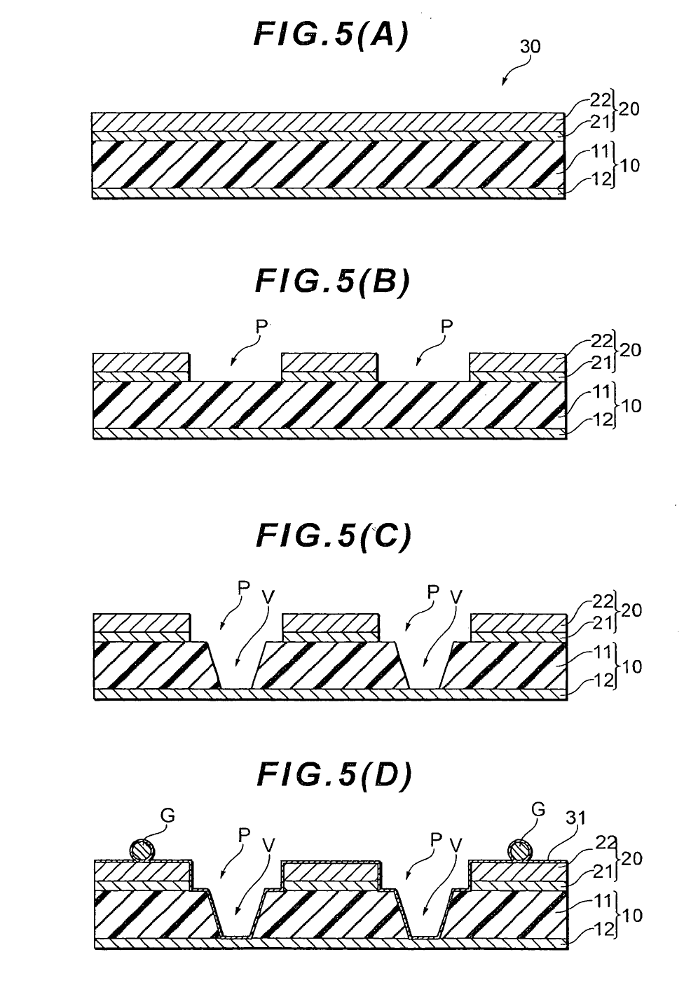

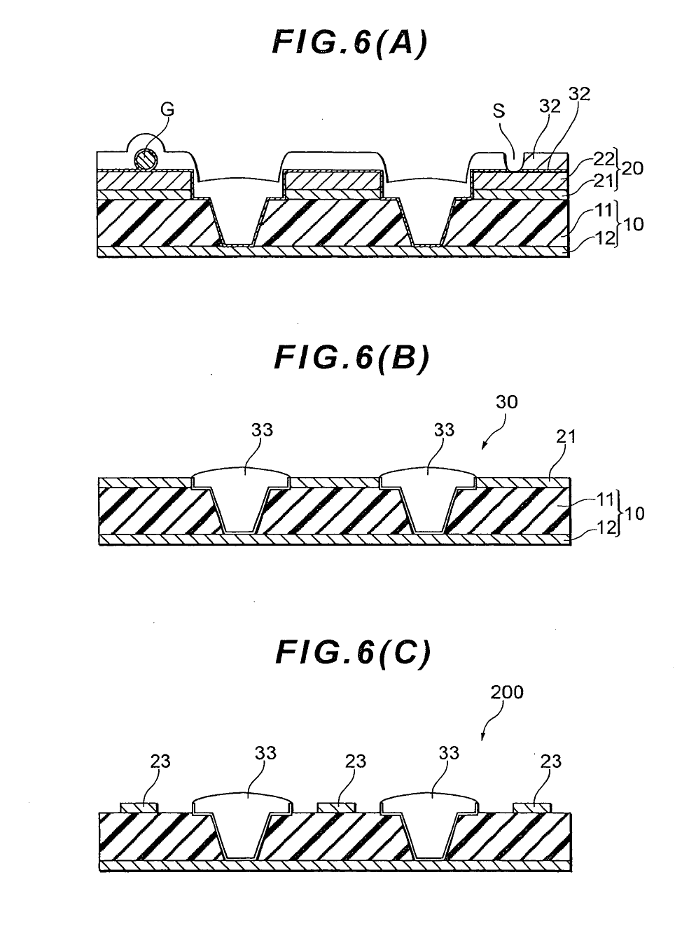

In contrast to this, the method for manufacturing a printed wiring board according to the present invention can avoid the occurrence of such inconvenience. Here, FIGS. 5(A) to (D) and FIGS. 6(A) to (C) are process flow charts illustrating an outline of procedural steps in one embodiment of a method for manufacturing a printed wiring board according to the present invention, and are similar to those illustrated in FIGS. 1(A) to (D) and FIGS. 2(A) to (C), except that a foreign matter G such as a fine particle and dust has deposited on a carrier foil layer 22 of a metal foil 20 provided with a carrier foil before a seed layer 31 is formed or while the seed layer 31 is formed.

In other words, the seed layer 31 can be formed so as to take in the foreign matter G (FIG. 5(D)) in such a state that the foreign matter G deposits on the carrier foil layer 22, so that when the seed layer 31 is grown by conducting an electrolytic plating process in this state, an uneven shape can be formed in a plated film 32 to be formed, which can be a recess part (dropout portion S) produced by a drop of the foreign matter G, or can be a projecting part formed in a portion in which the foreign matter G remains (FIG. 6(A)). However, a manufacturing method according to the present invention peels and removes the carrier foil layer 22 from a metal foil layer 21, so that the unevenness produced in the plated film 32 is consequently removed (FIG. 6(B)). Accordingly, the influence of the unevenness due to the deposition of the foreign matter G can be removed, so that a wiring pattern 23 which is formed by the patterning of the metal foil layer 21 is not affected by such an inconvenience.

As was described above, the present invention is not limited to each of the above described embodiments, but changes can be appropriately made in such a range as not to deviate from the scope. For instance, the conductors of metal foil layers 12 and 21 are not limited to a copper foil, but may employ a layer of another metal. Furthermore, the electronic components (embedded element) to be embedded in a printed wiring board 100 are not limited to the above components, but other various electronic components (chip component of single L, C and R, array of L, C and R, LCR multiple chip component with the use of ceramic multilayer substrate, and the like) may be embedded.

An aperture P and a via hole V may be formed at a time (continuously without stopping). In this case, such a method can be exemplified as to form the aperture P and the via hole V in one step while using the same working medium, in other words, while making the working medium such as a laser beam and blast beads directly project to or irradiate the metal foil 20 provided with the carrier foil, without selectively removing and patterning the metal foil 20 provided with the carrier foil of a composite 15 with the use of a photolithographic technology and an etching technique. At this time, conformal processing can be performed in the step, when the beam diameter or shot diameter of the working medium (diameter of continuous laser beam or diameter of pulse laser beam, for instance) is not substantially changed. Large window processing can be performed when the beam diameter or shot diameter of the working medium is reduced after the aperture P has been formed.

The method for manufacturing a printed wiring board according to the present invention bonds a metal foil provided with a carrier foil onto an insulator so that the metal foil layer can contact one surface of the insulator, then forms a hole, fills the via with a metal, and then peels the carrier foil layer of the metal foil provided with the carrier foil from the metal foil layer; thereby can surely form a fine wiring pattern having a small layer thickness from the metal foil layer while enhancing the productivity by simplifying the process, when forming a wiring structure having a filled via; and accordingly can be widely and effectively used as a printed wiring board, a multilayer wiring board and the like which have various electronic components embedded therein, in an equipment, a device, a system and a facility equipped with those, and in manufacture therefor.

The present application is based on Japanese priority application No. 2008-238268 filed on Sep. 17, 2008, the entire contents of which are hereby incorporated by reference.

What is claimed is:

1. A method for manufacturing a printed wiring board comprising the steps of:
forming a conductive layer on the other surface of an insulator;
bonding a metal foil provided with a carrier foil having a carrier foil layer and a metal foil layer onto the insulator so that the metal foil layer can contact one surface of the insulator;
forming at least one hole in the metal foil provided with the carrier foil and the insulator so that the conductive layer formed on the other surface of the insulator can be exposed from the metal foil provided with the carrier foil;
filling the hole with a conductor by conducting plating on the metal foil provided with the carrier foil and on the inner part of the hole; and
peeling the carrier foil layer of the metal foil provided with the carrier foil from the metal foil layer.

2. The method for manufacturing the printed wiring board according to claim 1, wherein the carrier foil layer is a metal.

3. The method for manufacturing the printed wiring board according to claim 1, further comprising a step of forming a wiring pattern on the metal foil layer bonding to the one surface of the insulator.

4. The method for manufacturing the printed wiring board according to claim 1, wherein
the step of forming the hole includes:
a step of forming at least one aperture in the metal foil provided with the carrier foil so that one surface of the insulator can be exposed from the metal foil provided with the carrier foil; and
a step of forming at least one connection hole in the insulator in at least the one aperture so that the conductive layer formed on the other surface of the insulator can be exposed.

5. The method for manufacturing the printed wiring board according to claim 4, wherein the connection hole is formed by making a working medium having a larger beam diameter or shot diameter than that of the aperture project to or irradiate the insulator from above the aperture, in the step of forming the hole.
